(19) United States
(12) Patent Application Publication
(10) Pub. No.: US 2025/0290013 A1
(43) Pub. Date: Sep. 18, 2025

(54) CLEANING SOLUTION COMPOSITION USED AFTER METAL FILM POLISHING

(71) Applicant: KCTECH CO., LTD., Gyeonggi-do (KR)

(72) Inventors: Yong Ho JEONG, Gyeonggi-do (KR); Kun Hee PARK, Gyeonggi-do (KR); Jin Hwi PARK, Gyeonggi-do (KR); Kyo Wook HWANG, Gyeonggi-do (KR)

(73) Assignee: KCTECH CO., LTD., Gyeonggi-do (KR)

(21) Appl. No.: 19/071,751

(22) Filed: Mar. 6, 2025

(30) Foreign Application Priority Data
Mar. 12, 2024 (KR) 10-2024-0034772

(51) Int. Cl. C11D 7/32

(52) U.S. Cl. CPC C11D 7/3209; C11D 7/3245; C11D 7/3281; C11D 2111/16; C11D 2111/22

(57) ABSTRACT

Provided is a cleaning solution composition containing a chelating agent containing amino acid, a pH adjuster containing a quaternary ammonium compound, an etchant containing an amine compound, and an inhibitor containing pyridinecarboxylic acid, wherein the cleaning solution composition does not contain an azole compound.

### CROSS-REFERENCE TO RELATED APPLICATION

This application claims the benefit of Korean Patent Application No. 10-2024-0034772 filed on Mar. 12, 2024, in the Korean Intellectual Property Office, the entire disclosure of which is incorporated herein by reference for all purposes.

### BACKGROUND

### 1. Field of the Invention

One or more embodiments relate to a cleaning solution composition used after metal film polishing.

### 2. Description of the Related Art

Wafers are used to form integrated circuits in microelectronic devices. A wafer contains a material such as silicon, and has areas patterned for deposition of different materials having insulating, conductive, or semiconductive properties in the wafer. In order to achieve accurate patterning, it is necessary to remove excess materials used to form layers on the wafer. Also, in order to manufacture functional and reliable circuits, it is important to manufacture a flat or planar microelectronic wafer surface prior to subsequent processing. Therefore, it is necessary to remove and/or polish a specific surface of the microelectronic device wafer.

Chemical mechanical polishing (CMP) is a process in which an arbitrary material is removed from a surface of a microelectronic device wafer and the surface is polished by a combination of a physical process such as polishing and a chemical process such as oxidation or chelation. In its most basic form, in the CMP, a slurry, for example, a solution of an abrasive and an active compound, is applied to a polishing pad, and the polishing pad applied with the slurry buffs away, removes, planarizes, and polishes a surface of a microelectronic device wafer. In addition, in the manufacturing of integrated circuits, the CMP slurry needs to be capable of preferentially removing a film including composite layers of metals and other materials, so that a highly flat surface may be generated on a wafer for subsequent lithography or patterning, etching, and thin film processing.

After the CMP process, residues generated during various processing operations, including multilayer film formation, etching, and CMP process, and the like or contaminants such as particles resulting from removed layers, are generated. These residues or contaminants cause damage to wiring during subsequent steps for forming metal wiring or various structures, increase damage to a surface of a structure, and cause poor electrical performance of a semiconductor device. Therefore, after the CMP process, a cleaning process is performed as an essential subsequent step to remove the residues or contaminants.

However, since a cleaning solution composition generally used for cleaning after the polishing is an alkaline aqueous solution rich in OH, it charges abrasive particles and a wafer surface, making it easy to remove the abrasive particles through electrical repulsion, but impurities such as metal contaminants and organic contaminants on the wafer surface may not be effectively removed after cleaning. Particularly, a cleaning solution composition containing an azole compound used in the related art has a problem in that it remains on the wafer surface after cleaning and acts as an organic defect.

In addition, the cleaning solution may unintentionally corrode metal wiring materials formed on a wafer, which may cause problems such as a decrease in reliability and quality of a manufactured semiconductor.

### SUMMARY

Embodiments provide a cleaning solution composition used after metal film polishing that is capable of effectively removing metal contaminants and organic contaminants generated after chemical mechanical polishing (CMP) of a metal film.

However, technical goals to be achieved are not limited to those described above, and other goals not mentioned above can be clearly understood by one of ordinary skill in the art from the following description.

According to an aspect, there is provided a cleaning solution composition containing a chelating agent containing amino acid, a pH adjuster containing a quaternary ammonium compound, an etchant containing an amine compound, and an inhibitor containing pyridinecarboxylic acid, wherein the cleaning solution composition does not contain an azole compound.

The amino acid may be one or more selected from the group consisting of cysteine, histidine, proline, arginine, glycine, lysine, and leucine.

The quaternary ammonium compound may contain at least one selected from the group consisting of tris(hydroxyethyl)methylammonium hydroxide (THEMAH), tetramethylammonium hydroxide (TMAH), choline hydroxide, tetraethylammonium hydroxide (TEAH), tetrabutylammonium hydroxide (TBAH), and ethyltrimethylammonium hydroxide (ETMAH).

The amine compound may contain one or more selected from the group consisting of monoethanolamine, diethanolamine, triethanolamine, ethylenediamine, diethylenetriamine, diethylamine, triethylamine, diethylhydroxylamine, and triethylenetetramine.

The pyridinecarboxylic acid may contain one or more selected from the group consisting of nicotinic acid, quinolinic acid, and isonicotinic acid.

A content of the amino acid may be 0.1 wt % to 5 wt % with respect to a total content of the cleaning solution composition.

A content of the quaternary ammonium compound may be 0.1 wt % to 10 wt % with respect to a total content of the cleaning solution composition.

A content of the amine compound may be 0.1 wt % to 10 wt % with respect to a total content of the cleaning solution composition.

A content of the pyridinecarboxylic acid may be 0.01 wt % to 5 wt % with respect to a total content of the cleaning solution composition.

A pH of the cleaning solution composition may be 8 to 13.

The cleaning solution composition may be used in a brush cleaning step of a substrate after polishing a metal film.

A polishing rate for a copper (Cu) film may be 1.0 Å/min or less.

After cleaning, an inhibitor may not remain on a surface of a metal polishing film.

According to another aspect, there is provided a method of cleaning a wafer for a semiconductor device, the method including, after polishing a polishing film including a metal formed on the wafer for the semiconductor device, cleaning the wafer for the semiconductor device using the cleaning solution composition described above.

The metal may contain one or more selected from the group consisting of copper (Cu), cobalt (Co), ruthenium (Ru), tungsten (W), tantalum nitride (TaN), molybdenum (Mo), and titanium (Ti).

Additional aspects of embodiments will be set forth in part in the description which follows and, in part, will be apparent from the description, or may be learned by practice of the disclosure.

According to embodiments, the cleaning solution composition used after polishing a metal film has an effect of suppressing corrosion of metal wiring formed on a wafer while removing metal contaminants and organic impurities generated after CMP of a metal film formed on the wafer.

It should be understood that the effects of the present disclosure are not limited to the above-described effects, but are construed as including all effects that can be inferred from the configurations and features described in the following description or claims of the present disclosure.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 illustrates an evaluation result of defects of a wafer after cleaning using a composition according to an embodiment; and

FIG. 2 illustrates an evaluation result of remaining organic matters of a wafer after cleaning using a composition according to an embodiment.

### DETAILED DESCRIPTION

Hereinafter, embodiments will be described in detail. However, various alterations and modifications may be made to the embodiments. Here, the embodiments are not construed as limited to the disclosure. The embodiments should be understood to include all changes, equivalents, and replacements within the idea and the technical scope of the disclosure.

The terminology used herein is for the purpose of describing particular embodiments only and is not to be limiting of the embodiments. The singular forms “a”, “an”, and “the” are intended to include the plural forms as well, unless the context clearly indicates otherwise.

It will be further understood that the terms “comprises/comprising” and/or “includes/including” when used herein, specify the presence of stated features, integers, steps, operations, elements, and/or components, but do not preclude the presence or addition of one or more other features, integers, steps, operations, elements, components and/or groups thereof.

Unless otherwise defined, all terms including technical and scientific terms used herein have the same meaning as commonly understood by one of ordinary skill in the art to which the embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

When describing the embodiments with reference to the accompanying drawings, like reference numerals refer to like components and a repeated description related thereto will be omitted. In the description of embodiments, detailed description of well-known related structures or functions will be omitted when it is deemed that such description will cause ambiguous interpretation of the present disclosure.

In addition, the terms first, second, A, B, (a), and (b) may be used to describe constituent elements of the embodiments. These terms are used only for the purpose of discriminating one component from another component, and the nature, the sequences, or the orders of the components are not limited by the terms.

A component, which has the same common function as a component included in any one embodiment, will be described by using the same name in other embodiments. Unless disclosed to the contrary, the description of any one embodiment may be applied to other embodiments, and the specific description of the repeated configuration will be omitted.

It will be understood that when a certain part “includes” a certain component, the part does not exclude another component but may further include another component.

The present disclosure relates to a cleaning solution composition containing a chelating agent containing amino acid, a pH adjuster containing a quaternary ammonium compound, an etchant containing an amine compound, and an inhibitor containing pyridinecarboxylic acid, wherein the cleaning solution composition does not contain an azole compound.

The cleaning solution composition according to the present disclosure may contain a chelating agent. The chelating agent may prevent the redeposition of a removed metal onto a semiconductor surface, thereby improving a removal effect of polishing fine particles, metal impurities, and the like remaining on a wafer for a semiconductor device. In addition, the chelating agent may provide a cleaning effect for polishing particles, organic matters, impurities, and the like remaining after a polishing step, along with the function of a pH buffer in the cleaning solution composition.

According to an embodiment, the chelating agent may contain an amino acid, and the amino acid may be one or more selected from the group consisting of cysteine, histidine, proline, arginine, glycine, lysine, and leucine.

According to an embodiment, a content of the amino acid may be 0.1 wt % to 5 wt %, and desirably 0.5 wt % to 3 wt % with respect to a total content of the cleaning solution composition. When the content of amino acid is less than the lower limit, the effect of removing contaminants such as polishing fine particles, metal impurities, and the like may be reduced, and when the content of amino acid exceeds the upper limit, a problem of amino acid not being sufficiently dissolved and adsorbed on a wafer surface may occur.

The cleaning solution composition according to the present disclosure may contain a pH adjuster. The pH adjuster may contain a quaternary ammonium compound, and the quaternary ammonium compound may contain at least one selected from the group consisting of tris(hydroxyethyl)methylammonium hydroxide (THEMAH), tetramethylammonium hydroxide (TMAH), choline hydroxide, tetraethylammonium hydroxide (TEAH), tetrabutylammonium hydroxide (TBAH), and ethyltrimethylammonium hydroxide (ETMAH). According to an embodiment, a content of the quaternary ammonium compound may be 0.1 wt % to 10 wt % with respect to the total content of the cleaning solution composition.

The pH of the cleaning solution composition may be appropriately adjusted using the pH adjuster, and the pH of the cleaning solution composition with the adjusted pH may be 8 to 13, desirably 10 to 12. When the pH is less than the above range, a problem of corrosion occurring in metals such as copper may occur.

The cleaning solution composition according to the present disclosure may contain an etchant, and the etchant may contain an amine compound. CuOₓ formed after the polishing step combines with organic matters such as azole to induce organic defects, and the etchant in the composition reduces CuOₓ to a Cu hydroxide complex and dissolves and removes it. According to an embodiment, the amine compound may contain one or more selected from the group consisting of monoethanolamine, diethanolamine, triethanolamine, ethylenediamine, diethylenetriamine, diethylamine, triethylamine, diethylhydroxylamine, and triethylenetetramine. According to an embodiment, a content of the amine compound may be 0.1 wt % to 20 wt %, and desirably 1 wt % to 15 wt % with respect to the total content of the cleaning solution composition. When the content of the amine compound exceeds the upper limit, a problem of corrosion of Cu filled in a pattern may occur, and when the content of the amine compound is less than the lower limit, a problem of degraded detergency may occur.

The cleaning solution composition according to the present disclosure may contain an inhibitor. An inhibitor forms a coordination bond with Cu on a wafer surface, thereby protecting a surface of Cu and suppressing metal corrosion. In the present disclosure, the inhibitor may be a pyridine compound that does not contain NH₂ and an amine group, and desirably may be pyridinecarboxylic acids. According to an embodiment, the pyridinecarboxylic acids may contain one or more selected from the group consisting of nicotinic acid, quinolinic acid, and isonicotinic acid. According to an embodiment, a content of the pyridinecarboxylic acids may be 0.01 wt % to 5 wt % with respect to the total content of the cleaning solution composition. When the content of pyridinecarboxylic acids is less than the lower limit, a problem of Cu corrosion may occur, and when the content of pyridinecarboxylic acids exceeds the upper limit, a problem of defects occurring due to adsorption on the wafer surface may occur.

According to an embodiment, the cleaning solution composition according to the present disclosure may not contain an azole compound. Although the azole compound mainly acts as a corrosion inhibitor as the inhibitor in the cleaning solution composition, the azole compound may remain on the wafer surface after cleaning and may cause organic defects. Therefore, in the present disclosure, the inhibitor is replaced from the azole compound to pyridinecarboxylic acids, thereby exhibiting an effect of preventing organic contamination while enhancing the inhibition of metal corrosion.

The cleaning solution composition according to the present disclosure may be used in a brush cleaning step of a substrate after polishing a metal film. After a chemical mechanical polishing (CMP) step of a wafer for a semiconductor device, buffing and brush cleaning and de-ionized water (DI water) cleaning steps are performed, and the cleaning solution composition according to the present disclosure may be used in the buffing and brush cleaning step.

According to an embodiment, the cleaning solution composition may have a polishing rate of 1.0 Å/min or less for a copper (Cu) film, and after cleaning, the inhibitor may not remain on a surface of a metal polishing film. The cleaning solution composition according to the present disclosure has an effect of inhibiting corrosion on a metal film by containing the inhibitor, while having an effect of minimizing the amount of inhibitor remaining on the surface of the metal film by not containing an azole compound.

One aspect of the present disclosure provides a method of cleaning a wafer for a semiconductor device, the method including, after polishing a polishing film containing a metal formed on the wafer for the semiconductor device, cleaning the wafer for the semiconductor device using the cleaning solution composition described above. After the CMP step of the wafer for the semiconductor device, residues generated during polishing or contaminants such as particles resulting from a polished layer are generated. These residues or contaminants cause damage to wiring during subsequent steps for forming metal wiring or various structures, increase damage to a surface of a structure, and cause poor electrical performance of a semiconductor device. Therefore, a cleaning step is essential. The cleaning solution composition of the present disclosure may be used in the cleaning step, and when the cleaning solution composition of the present disclosure is used in the cleaning step, corrosion of preformed metal wiring may be minimized, and residues and contaminants may be effectively removed.

According to an embodiment, the metal formed on the wafer for the semiconductor device may contain one or more selected from the group consisting of copper (Cu), cobalt (Co), ruthenium (Ru), tungsten (W), tantalum nitride (TaN), molybdenum (Mo), and titanium (Ti).

Hereinafter, the present disclosure will be described in more detail with reference to examples. The following examples are provided for the purpose of illustrating the present disclosure and are not intended to limit the scope of the present disclosure.

### EXAMPLES

### 1. <Preparation Example>

Cleaning solution compositions of Examples 1 to 6 and Comparative Examples 1 to 6 having a pH of 12 to 13 were prepared by adding 7 wt % of monoethanolamine as an etchant, 7 wt % of THEMAH as a pH adjuster, and a chelating agent and an inhibitor according to Table 1 below.

TABLE 1

| | Chelating agent | | Inhibitor | |
|---|---|---|---|---|
| | | Content | | Content |
| | Type | (wt %) | Type | (wt %) |
| Example 1 | Cysteine | 2 | Nicotinic acid | 1 |
| Example 2 | Histidine | 2 | Nicotinic acid | 1 |
| Example 3 | Cysteine | 2 | Quinolinic acid | 1 |
| Example 4 | Histidine | 2 | Quinolinic acid | 1 |
| Example 5 | Cysteine | 2 | Isonicotinic acid | 1 |
| Example 6 | Histidine | 2 | Isonicotinic acid | 1 |
| Comparative | Cysteine | 2 | — | — |
| Example 1 | | | | |
| Comparative | Histidine | 2 | — | — |
| Example 2 | | | | |
| Comparative | Cysteine | 2 | Imidazole | 1 |
| Example 3 | | | | |
| Comparative | Cysteine | 2 | Benzotriazole | 1 |
| Example 4 | | | | |
| Comparative | Cysteine | 2 | 1,2,4-triazole | 1 |
| Example 5 | | | | |
| Comparative | Cysteine | 2 | 5-Amino-1H-tetrazole | 1 |
| Example 6 | | | | |

### 2. Experimental Example 1: Measurement of Degree of Corrosion of Metal

For the compositions of Examples 1 to 6 and Comparative Examples 1 to 6, degrees of corrosion for copper (Cu), cobalt (Co), and tungsten (W) were measured as etch rates (Å/min).

The results are shown in Table 2 below.

TABLE 2

| | Cu | Co | W |
|---|---|---|---|
| Example 1 | 0.82 | 1.38 | 5.80 |
| Example 2 | 0.90 | 1.37 | 5.85 |
| Example 3 | 0.84 | 1.22 | 5.81 |
| Example 4 | 0.91 | 1.41 | 5.90 |
| Example 5 | 0.88 | 1.34 | 5.84 |
| Example 6 | 0.95 | 1.40 | 5.91 |
| Comparative Example 1 | 1.93 | 3.45 | 6.09 |
| Comparative Example 2 | 1.98 | 3.36 | 6.11 |
| Comparative Example 3 | 1.37 | 2.44 | 6.13 |
| Comparative Example 4 | 1.14 | 2.06 | 5.96 |
| Comparative Example 5 | 1.39 | 2.11 | 6.17 |
| Comparative Example 6 | 1.22 | 2.28 | 6.02 |

### 3. Experimental Example 2: Measurement of Number of Defects

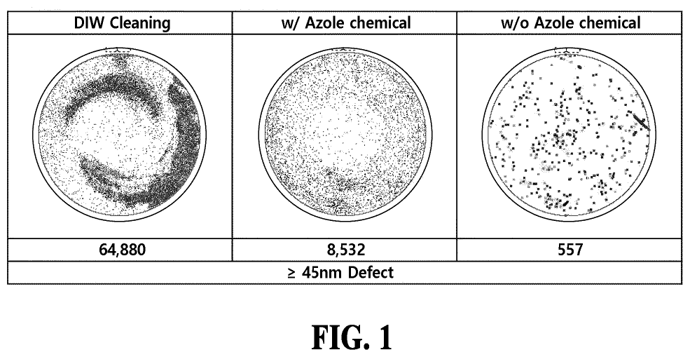

After a CMP process, wafer cleaning was performed using DIW, a composition containing an azole compound, and the composition of Example 1 not containing an azole compound, defect occurrence was measured, and the results thereof are shown in FIG. 1. “w/o Azole” indicates that the wafer was cleaned using the composition of Example 1, and “w/Azole” indicates that the wafer was cleaned using a composition containing an azole chemical.

Referring to FIG. 1, it may be seen that, even in a case of the composition of the comparative example containing the azole compound, the number of defects is improved compared to when only DIW is used for cleaning, however, the composition according to an embodiment of the present disclosure that does not contain the azole compound is far superior in terms of defect improvement.

### 4. Experimental Example 3: Evaluation of Organic Matter

To evaluate the amount of organic matter remaining after wafer cleaning using a cleaning solution, a corrosion voltage Ecorr was determined through Tafel analysis. As shown in Table 3 below, “Initial” indicates a corrosion voltage value measured without contamination of a Cu surface, and “Contamination” indicates a wafer contaminated by dipping a Cu wafer in azole-1 or azole-2. “w/o Azole” indicates that the contaminated wafer is cleaned using the composition of Example 1, and “w/Azole” indicates that the contaminated wafer is cleaned using the composition containing an azole chemical.

TABLE 3

| | Pre- | | | DIW |
|---|---|---|---|---|
| Evaluation method | processing | Contamination | Cleaning | Rinse |
| Initial | ◯ | — | — | ◯ |
| Contamination | ◯ | ◯ | — | ◯ |
| w/Azole | ◯ | ◯ | ◯ | ◯ |
| w/o Azole | ◯ | ◯ | ◯ | ◯ |

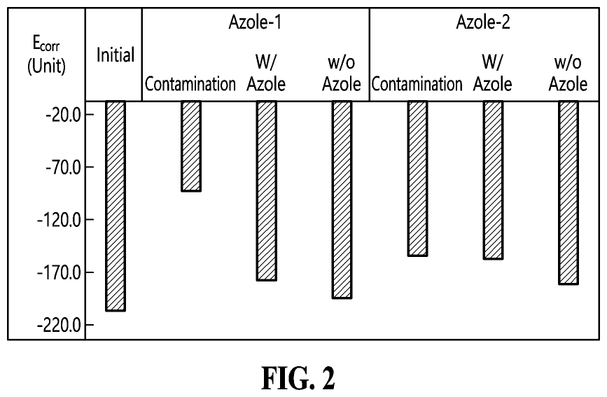

The results of Tafel analysis performed on each wafer are shown in Table 4 below and FIG. 2.

TABLE 4

| | Azole-1 | | | Azole-2 | | |
|---|---|---|---|---|---|---|
| Initial | Contamination | w/Azole | w/o Azole | Contamination | w/Azole | w/o Azole |
| −207.3 | −88.6 | −176.7 | −194.3 | −151.8 | −155.7 | −180.7 |

Referring to Table 4 and FIG. 2, it may be seen that Initial has a low corrosion voltage value because there is no inhibitor on the surface, and when the inhibitor such as azole is processed, the corrosion voltage value is measured to be high. Accordingly, it may be found that, when the cleaning is performed using the composition of Example 1 that does not contain the azole compound, the corrosion voltage value decreases closer to that of Initial than when the cleaning is performed using the cleaning solution composition containing the azole compound, indicating that organic contaminants are effectively removed.

While the embodiments are described with reference to drawings, it will be apparent to one of ordinary skill in the art that various alterations and modifications in form and details may be made in these embodiments without departing from the spirit and scope of the claims and their equivalents. For example, suitable results may be achieved if the described techniques are performed in a different order and/or if components in a described system, architecture, device, or circuit are combined in a different manner and/or replaced or supplemented by other components or their equivalents.

Therefore, other implementations, other embodiments, and equivalents to the claims are also within the scope of the following claims.

What is claimed is:

1. A cleaning solution composition comprising:
a chelating agent comprising amino acid;
a pH adjuster comprising a quaternary ammonium compound;
an etchant comprising an amine compound; and
an inhibitor comprising pyridinecarboxylic acid;
wherein the cleaning solution composition does not comprise an azole compound.

2. The cleaning solution composition of claim 1, wherein the amino acid is one or more selected from the group consisting of cysteine, histidine, proline, arginine, glycine, lysine, and leucine.

3. The cleaning solution composition of claim 1, wherein the quaternary ammonium compound comprises at least one selected from the group consisting of tris(hydroxyethyl)methylammonium hydroxide (THEMAH), tetramethylammonium hydroxide (TMAH), choline hydroxide, tetraethylammonium hydroxide (TEAH), tetrabutylammonium hydroxide (TBAH), and ethyltrimethylammonium hydroxide (ETMAH).

4. The cleaning solution composition of claim 1, wherein the amine compound comprises one or more selected from the group consisting of monoethanolamine, diethanolamine, triethanolamine, ethylenediamine, diethylenetriamine, diethylamine, triethylamine, diethylhydroxylamine, and triethylenetetramine.

5. The cleaning solution composition of claim 1, wherein the pyridinecarboxylic acid comprises one or more selected from the group consisting of nicotinic acid, quinolinic acid, and isonicotinic acid.

6. The cleaning solution composition of claim 1, wherein a content of the amino acid is 0.1 wt % to 5 wt % with respect to a total content of the cleaning solution composition.

7. The cleaning solution composition of claim 1, wherein a content of the quaternary ammonium compound is 0.1 wt % to 10 wt % with respect to a total content of the cleaning solution composition.

8. The cleaning solution composition of claim 1, wherein a content of the amine compound is 0.1 wt % to 10 wt % with respect to a total content of the cleaning solution composition.

9. The cleaning solution composition of claim 1, wherein a content of the pyridinecarboxylic acid is 0.01 wt % to 5 wt % with respect to a total content of the cleaning solution composition.

10. The cleaning solution composition of claim 1, wherein a pH is 8 to 13.

11. The cleaning solution composition of claim 1, wherein the cleaning solution composition is used in a brush cleaning step of a substrate after polishing a metal film.

12. The cleaning solution composition of claim 1, wherein a polishing rate for a copper (Cu) film is 1.0 Å/min or less.

13. The cleaning solution composition of claim 1, wherein after cleaning, an inhibitor does not remain on a surface of a metal polishing film.

14. A method of cleaning a wafer for a semiconductor device, the method comprising:
after polishing a polishing film comprising a metal formed on the wafer for the semiconductor device,
cleaning the wafer for the semiconductor device using the cleaning solution composition of claim 1.

15. The method of claim 14, wherein the metal comprises one or more selected from the group consisting of copper (Cu), cobalt (Co), ruthenium (Ru), tungsten (W), tantalum nitride (TaN), molybdenum (Mo), and titanium (Ti).
